(19) United States
(12) Patent Application Publication
(10) Pub. No.: US 2026/0360278 A1
(43) Pub. Date: Nov. 12, 2026

(54) SYSTEM FOR SIMULATED SEMICONDUCTOR WAFER PROCESSING

(71) Applicant: Roots Engineering Services, Venice, FL (US)

(72) Inventor: Jeffrey M Kondel, Venice, FL (US)

(21) Appl. No.: 19/124,921

(22) PCT Filed: Oct. 27, 2023
(86) PCT No.: PCT/US2023/036086

§ 371 Date: Apr. 28, 2025

Related U.S. Application Data
(60) Provisional application No. 63/420,191, filed on Oct. 28, 2022.

(51) Int. Cl. G09B 23/00

(52) U.S. Cl. CPC G09B 23/00

(57) ABSTRACT

Systems, methods, and curriculum for simulating semiconductor production and associated methods of using the same on a wafer suitable to produce a semiconductor. One or more barriers of a central laboratory hub of the system separate stations of system from a laboratory environment of the central laboratory hub. Each station is operatively coupled to the central laboratory hub such that the wafer may be positioned between the same. A deposition station is configured to deposit one or more layers of material suitable for the production of a semiconductor. A photomask station is configured to generate a photomask associated with the wafer. An etching station is configured to generate a circuit pattern within the photomask associated with the wafer. The system further includes a transportation system configured to operate within the laboratory environment and to transport the wafer from the central laboratory hub to one or more of the stations.

### FIELD

The present invention relates to systems associated with the production of semiconductors and, more particularly, to the simulated production of a semiconductor from a suitable wafer utilizing a mock clean room and a predetermined curriculum (e.g., didactic curriculum).

### BACKGROUND

From smartphones to aircraft, semiconductors evolved to improve technologies and do wonders for the convenience of everyday life. Semiconductors are typically generated from wafers of suitable materials utilizing a clean room that is substantially free of reactive contaminates. Stations, pods, cells, or the like are typically utilized in semiconductor production. Each station is generally suitable to perform one or more tasks associated with or required for semiconductor production. Semiconductor clean rooms are typically designed to control static, particulate matter, out-gassing, and other sources of contamination to protect workers and consumers, and to ensure success of the semiconductor manufacturing. Within numerous markets across the semiconductor industry, there is a growing need for qualified technicians to produce semiconductors.

However, the cost of constructing, maintaining, and stocking a semiconductor clean room is often prohibitively expensive for educational facilities, training facilities, or the like. Thus, semiconductor factory operators that are newly certified, qualified, or have recently completed training programs for operators of semiconductor production facilities may lack experience in the operation of such facilities and the equipment and instruments associated with or required in processes used in such facilities.

In view of the circumstances described above, there is a need for a system to provide experience in operating semiconductor production facilities and associated equipment and instruments for educational or training purposes.

### BRIEF SUMMARY

Embodiments of the present disclosure address the above needs and/or achieve other advantages by providing systems, apparatuses, and methods related to simulating the production of semiconductors from wafers suitable for the production of semiconductors. For instance, embodiments of the systems and methods disclosed herein may replicate the production of semiconductors to the degree required for educational purposes, to provide the equivalent experience as provided by the production of operable semiconductors, or both. A further advantage of the systems and associated methods disclosed herein is providing actual experience in wafer processing (e.g., processes associated with or required for semiconductor generation) without the expense, operational costs, and upkeep required for a semiconductor lab and an appropriate predetermined curriculum (e.g., didactic curriculum) suitable for the production of working semiconductors.

In certain aspects, the present disclosure is directed to a system for simulating the production of a semiconductor from a wafer suitable for use in the production of a semiconductor from the wafer. The system includes a central laboratory hub with one or more barriers. The barrier(s) substantially encloses a laboratory environment such that the barrier(s) define the laboratory environment. The system further includes two or more stations, and each station is operatively coupled to the central laboratory hub such that the wafer may be selectively positioned between the respective station and the laboratory environment. The stations include a deposition station configured to deposit one or more layers of material suitable for the production of a semiconductor. The stations further include a photomask station configured to generate a photomask associated with the wafer. The stations also include an etching station configured to generate a circuit pattern within the photomask associated with the wafer. The system further includes a transportation system configured to operate within the laboratory environment and to transport the wafer from the central laboratory hub to one or more stations of the stations.

In at least one embodiment, the transportation system may include one or more robotic transportation devices. In additional or alternative embodiments, the robotic transportation device(s) may be configured to transport and/or manipulate a Front Opening Universal Pod. In additional or alternative embodiments, the transportation system may include two or more robotic transportation devices. In some embodiments, each robotic transportation device may be configured to transport and/or manipulate a Front Opening Universal Pod associated with the respective robotic transportation device. In an additional or alternative embodiment, one or more stations may each include a robotic manipulation device associated with the respective station. In some embodiments, two or more stations may each include a robotic manipulation device associated with the respective station. In a further or alternative embodiment, each station may include a robotic manipulation device associated with the respective station.

In an additional or alternative embodiment, the stations may include a bonding station configured to bond the wafer with an additional wafer, a carrier, or both. The additional wafer may be suitable for use in the production of an additional semiconductor from the additional wafer. The carrier may be configured to enhance the handling capability of, improve the electrical performance of, and/or reduce the susceptibility of a semiconductor produced from the wafer. In an additional or alternative embodiment, the stations may include a polishing station configured to remove subsurface damage associated with the wafer.

In a further or alternative embodiment, the wafer may undergo a photolithography step before subsequent etching. After the photolithography step, the wafer is moved to an etching station configured to selectively remove material from the layer(s) of material in order to create a chip pattern within the layer(s) of material. In an additional or alternative embodiment, the stations may include a stripping station configured to remove residual photoresist material.

In an additional or alternative embodiment, the stations may include a cleaning and inspection station configured to assess the alignment of the wafer, portions of the wafer, or both. In an additional or alternative embodiment, the stations may include a surface preparation station configured to grind the wafer to the correct size, to shape one or more edges of the wafer, or both. In an additional or alternative embodiment, the stations may include a metrology station configured for inspection of the wafer and/or thin film in-line section after semiconductor processing. In an additional or alternative embodiment, the stations may include a debonding station configured to separate the wafer and the additional wafer, the carrier, or both after bonding.

In another aspect, the present disclosure is directed to a method of simulating the production of a semiconductor from a wafer. The method includes positioning the wafer from the laboratory environment to a deposition station utilizing a transportation system configured to operate within a laboratory environment defined by at least one barrier of a central laboratory hub that substantially enclose the laboratory environment. Additionally, the method includes depositing one or more layers of material suitable for the production of a semiconductor to the wafer. The method further includes positioning the wafer from the laboratory environment to a photomask station utilizing the transportation system. The method also includes generating a photomask associated with the wafer. Another element of the method includes positioning the wafer from the laboratory environment to the etching station utilizing the transportation system. The method additionally includes generating a circuit pattern within the photomask associated with the wafer.

In at least one embodiment, the method may include positioning the wafer from the laboratory environment to an etching station utilizing the transportation system. Additionally or alternatively, the method may include selectively removing material from the at least one layer of material in order to create a chip pattern within the at least one layer of material. In an additional or alternative embodiment, the method may include positioning the wafer from the etching station to the laboratory environment utilizing the transportation system. In additional or alternative embodiments, the method may include positioning the wafer from the deposition station to the laboratory environment utilizing the transportation system.

Additional or alternative embodiments of the method may include positioning two or more wafers in the laboratory environment. Each of the wafers may be suitable for use in the production of a semiconductor. In an additional or alternative embodiment, the wafers may be loaded into one or more repository units positioned within the laboratory environment. In additional or alternative embodiments, the method may include loading two or more wafers into one or more repository units associated with the transportation system. Each of the wafers may be suitable for use in the production of a semiconductor.

The features, functions, and advantages that have been discussed may be achieved independently in various embodiments of the present invention or may be combined in yet other embodiments, further details of which can be seen with reference to the following description and drawings. Embodiments of the invention can include one or more or any combination of the above features and configurations.

Additional features, aspects and advantages of the invention will be set forth in the detailed description, which follows, and in part will be readily apparent to those skilled in the art from that description or recognized by practicing the invention as described herein. It is to be understood that both the foregoing general description and the following detailed description present various embodiments of the invention, and are intended to provide an overview or framework for understanding the nature and character of the invention as it is claimed. The accompanying drawings are included to provide a further understanding of the invention, and are incorporated in and constitute a part of this specification.

### BRIEF DESCRIPTION OF THE SEVERAL VIEWS OF THE DRAWINGS

These and other features, aspects and advantages of the present invention are better understood when the following detailed description of the invention is read with reference to the accompanying drawings, in which:

FIG. 1 illustrates a top environmental view of a system for simulating the production of a semiconductor from a suitable wafer, according to an exemplary aspect of the present disclosure;

FIG. 2 illustrates a top perspective view of a laboratory environment and associated stations of the system, according to an exemplary aspect of the present disclosure;

FIG. 3 illustrates a top view of the laboratory environment, according to an exemplary aspect of the present disclosure;

FIG. 4 illustrates a top view of a station of the system configured as a bonding station, according to an exemplary aspect of the present disclosure;

FIG. 5 illustrates a top view of a station of the system configured as a deposition station, according to an exemplary aspect of the present disclosure;

FIG. 6 illustrates a top view of a station of the system configured as a polishing station, according to an exemplary aspect of the present disclosure;

FIG. 7 illustrates a top view of a station of the system configured as a photomask station, according to an exemplary aspect of the present disclosure;

FIG. 8 illustrates a top view of a station of the system configured as an etching station, according to an exemplary aspect of the present disclosure;

FIG. 9 illustrates a top view of a station of the system configured as a stripping station, according to an exemplary aspect of the present disclosure;

FIG. 10 illustrates a top view of a station of the system configured as a cleaning and inspection station, according to an exemplary aspect of the present disclosure;

FIG. 11 illustrates a top view of a station of the system configured as a surface preparation station, according to an exemplary aspect of the present disclosure;

FIG. 12 illustrates a top view of a station of the system configured as a metrology station, according to an exemplary aspect of the present disclosure; and

FIG. 13 illustrates a top view of a station of the system configured as a debonding station, according to an exemplary aspect of the present disclosure.

Like reference numerals in the drawings may represent and refer to the same, analogous, or similar elements, features, or functions.

### DETAILED DESCRIPTION OF EMBODIMENTS OF THE INVENTION

Embodiments of the present invention will now be described more fully hereinafter with reference to the accompanying drawings, in which some, but not all, embodiments of the invention are shown. Indeed, the invention may be embodied in many different forms and should not be construed as limited to the embodiments set forth herein; rather, these embodiments are provided so that this disclosure will satisfy applicable legal requirements. Like numbers refer to like elements throughout. Unless described or implied as exclusive alternatives, features throughout the drawings and descriptions should be taken as cumulative, such that features expressly associated with some particular embodiments can be combined with other embodiments. Unless defined otherwise, technical and scientific terms used herein have the same meaning as commonly understood to one of ordinary skill in the art to which the presently disclosed subject matter pertains.

The exemplary embodiments are provided so that this disclosure will be both thorough and complete, and will fully convey the scope of the invention and enable one of ordinary skill in the art to make, use, and practice the invention.

The terms “coupled,” “fixed,” “attached to,” “communicatively coupled to,” “operatively coupled to,” and the like refer to both (i) direct connecting, coupling, fixing, attaching, communicatively coupling, and operatively coupling; and (ii) indirect connecting coupling, fixing, attaching, communicatively coupling, and operatively coupling via one or more intermediate components or features, unless otherwise specified herein. “Communicatively coupled to” and “operatively coupled to” can refer to physically and/or electrically related components.

While certain exemplary embodiments have been described and shown in the accompanying drawings, it is to be understood that such embodiments are merely illustrative of, and not restrictive on, the broad invention, and that this invention not be limited to the specific constructions and arrangements shown and described, since various other changes, combinations, omissions, modifications and substitutions, in addition to those set forth in the above paragraphs, are possible. Those skilled in the art will appreciate that various adaptations, modifications, and combinations of the herein described embodiments can be configured without departing from the scope and spirit of the invention. Therefore, it is to be understood that, within the scope of the included claims, the invention may be practiced other than as specifically described herein.

The inventive concepts disclosed herein are generally directed to systems, classrooms, training facilities, and/or mock semiconductor laboratories suitable to replicate the production of a semiconductor from a wafer for educational purposes and to provide users with experience in semiconductor production. Particularly, such educational and training goals may be achieved without the unnecessary costs and burden associated with a vacuum or neutral laboratory environment, e.g., an environment suitable for the production of a working semiconductor from the same wafers. Aspects of the present disclosure allow for users to identify whether processes performed meet expectations at each station and/or stage associated with disclosed systems, associated classrooms, and methods. The stations may generally be arranged as cells associated with a “mock clean room” such that users (e.g., students) may create, align, and adjust wafers and maintain the process in which a wafer would typically be manufactured into a working semiconductor, excluding the clean room. Thus, aspects of the present disclosure allow for simulating the production of a semiconductor from a wafer.

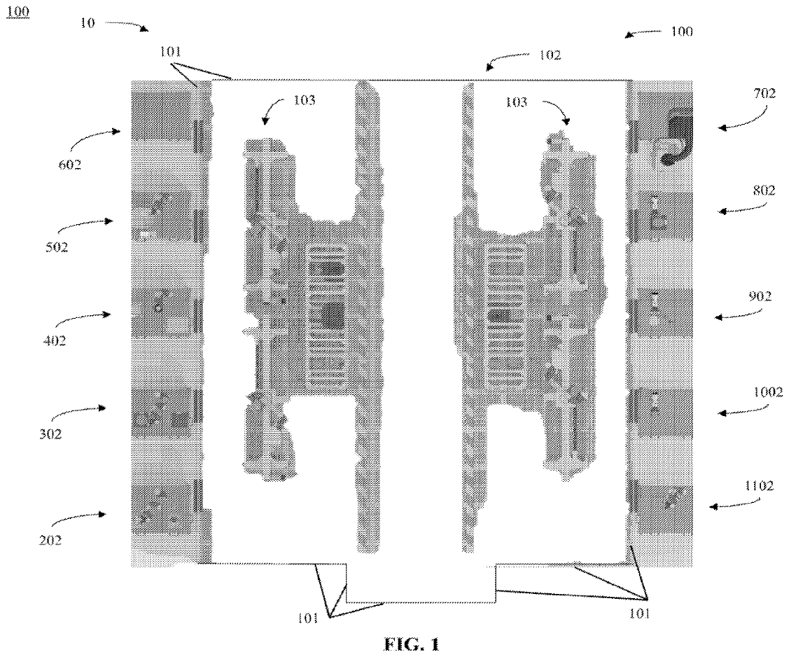

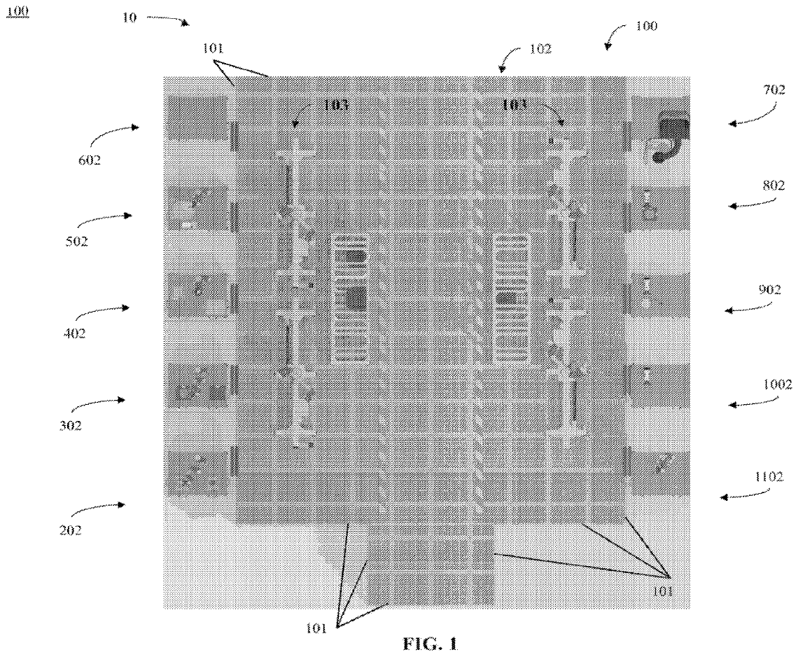

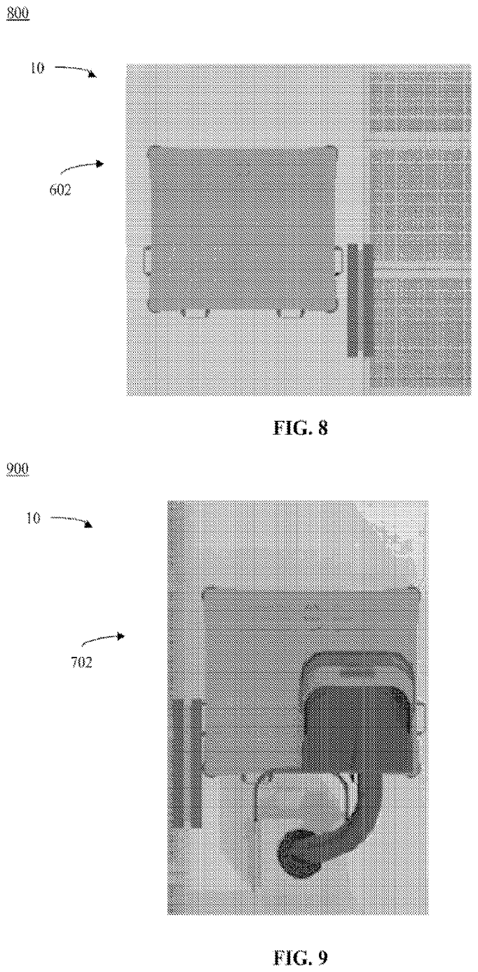

For instance, and referring generally to FIGS. 1-13, embodiments of a system 10 for simulating the production of a semiconductor are depicted in accordance with aspects of the present disclosure. The system may generally process a wafer suitable for use in the production of a semiconductor from the wafer by transporting the wafer between a laboratory environment 102 and two or more stations configured for one or more wafer processing steps. For example, various embodiments of the system 10 may be suitable to produce a working and/or operable semiconductor from the wafer if the laboratory environment 102 were configured as a sterile or clean laboratory environment (e.g., an environment substantially free of reactive contaminates; a vacuum; and/or an environment containing gases that are substantially non-reactive, noble gases, stable compounds of gases, or the like). Thus, embodiments of the present system and associated methods allow users to recognize the steps in the process of producing a semiconductor, implement some or all of the steps in producing a semiconductor, and monitor robotic processes associated with the production of a semiconductor in a mock clean room and/or respective stations of the system 10.

As shown particularly in FIG. 1, embodiments of the system 10 may include a central laboratory hub 100 with one or more barriers 101, such as four or more barriers 101. The barrier(s) 101 may substantially encloses a laboratory environment 102 such that the barrier(s) 101 define the laboratory environment 102. An exemplary embodiment of the central laboratory hub 100 may be define a floor footprint of approximately 20 feet by 25 feet. However, it should be appreciated that the central laboratory hub 100 may define any shape of the laboratory environment 102 desired or required and may include any appropriate number of barriers 101 to fully or partially enclose the laboratory environment 102.

In some embodiments, the central laboratory hub 100 and/or barriers(s) 101 may be configured as skeleton style clean room, creating the conception of a clean room without the cost of major construction or facility changes. To reduce costs associated with the system 10 and in some embodiments, the central laboratory hub 100 may not include a ceiling barrier, unlike a clean room configured to produce operational semiconductors from suitable wafers. Additionally or alternatively, the system 10 may simulate an environment in which the concentration of airborne particles is controlled. Additionally or alternatively, the system 10, the central laboratory hub 100, barriers(s) 101, and/or associated stations of the system 10 may be configured to implement and/or simulate current practices in semiconductor production while minimizing the introduction, generation, and retention of particles inside the room. Furthermore and in some embodiments, other relevant parameters, such as temperature, humidity, and pressure may be controlled as necessary within the laboratory environment 102 and/or one or more of the associated stations.

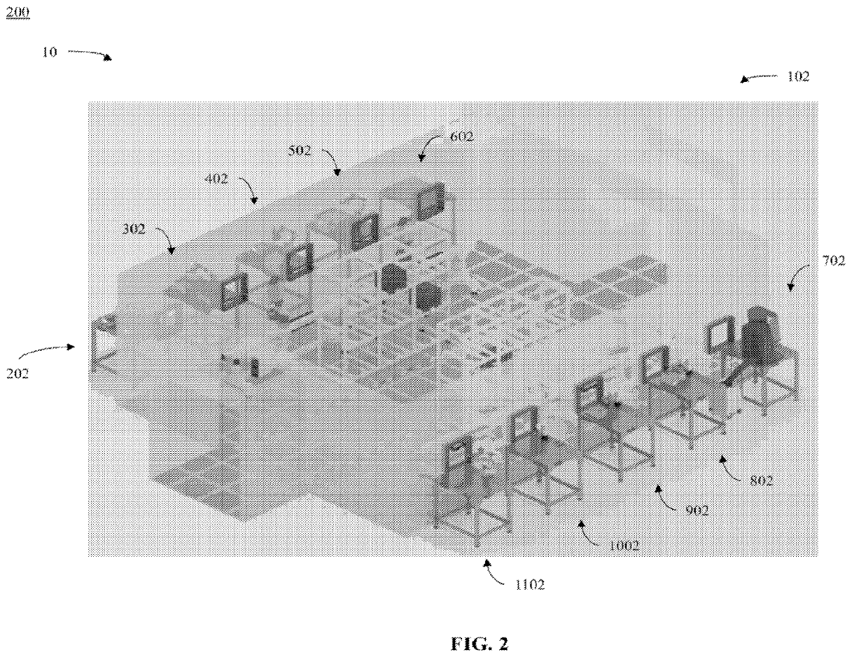

As shown in FIGS. 1 and 2, the system 10 further two or more stations (e.g., any of station 202, station 302, station 402, station 502, station 602, station 702, station 802, station 902, station 1002, station 1102, or additional or alternative stations configured to simulate one or more process associated with producing a semiconductor from a suitable wafer). Each station may be operatively coupled to the central laboratory hub 100 such that a wafer for processing may be selectively positioned between the respective station and the laboratory environment 102. The system 10 may include a transportation system 103 (see FIG. 1) positioned fully or partially within the laboratory environment 102. The transportation system 103 operates within, at least, the laboratory environment 102 in order to transport the wafer for processing from the central laboratory environment 102 to one or more stations of the stations.

As shown in the exemplary embodiment of FIG. 3, the transportation system 103 may include one or more robotic transportation devices 105. Each robotic transportation device 105 may be operatively coupled to a track 107. As shown and in some embodiments, each robotic transportation device 105 may be operably coupled to a slide, slide assembly, in order to allow the transportation device 105 to transport the wafer between one or more stations of the system 10 and the laboratory environment 102. However, other embodiments of the transportation system 103 may include additional or alternatively configured transportation devices (e.g., one or more self-propelled drones, actuatable robotic arms, etc.) capable of transferring, positioning, or the like the wafer from one or more of the stations and the laboratory environment 102. Additionally or alternatively, the robotic transportation device(s) 105 may be configured to transport and/or manipulate one or more repository units suitable to contain multiple wafers, such as a Front Opening Universal Pod (e.g., a FOUP 109 as illustrated). The each repository unit, FOUP 109, or the like may contain one or more wafers suitable for use by the system 10. In some embodiments, each robotic transportation device 105 may be configured to transport and/or manipulate a FOUP 109 associated with the respective robotic transportation device 105.

In some embodiments, the transportation system 103, one or more transportation devices 105, such as all of the transportation devices 105, and/or the FOUP(s) 109 may each include a tracking device (e.g., a RFID transmitter, receiver, transceiver, or the like). Embodiments of system 10, transportation system 103, and/or FOUP(s) 109 that include tracking device(s) may allow for an associated computer, controller, or processor to implement suitable instructions to determine the location of the respective transportation device 105, an associated FOUP(s) 109, and/or a wafer for processing relative to the laboratory environment 102 or one or more of the associated stations.

An element of simulating the production of a semiconductor from a wafer may include loading the laboratory environment 102 (e.g., a skeleton clean room, a mock clean room, or the like) with multiple wafers suitable for use in the production of a semiconductor. For example, two or more wafers, such as a stack of wafers may be positioned within the laboratory environment 102, loaded into the associated repository unit(s), and/or loaded into the associated FOUP(s) 109. Materials suitable for inclusion in the wafer include, but are not limited to, silicon; argon; germanium; oxides such as silicon oxides; silicon oxynitride compounds; indium gallium arsenide (InGaAs); metals such as copper or aluminum; nitrides; glasses; ceramics; glass ceramics; alloys of semiconductors; doped alloys of semiconductors; compound semiconductors such as GaAs, GaN, InP, etc.; organic semiconductor materials; and/or the like.

As shown in FIGS. 1-13, one or more stations of the system may each include a robotic manipulation device 111 associated with the respective station. The robotic manipulation devices 111 may generally include one or more robotic arms, actuatable arms, telescoping arms, or additional or alternative robotic devices suitable for the processes simulated within the respective stations. In some embodiments, two or more stations may each include a robotic manipulation device 111 associated with the respective station. In a further or alternative embodiment, each station may include a robotic manipulation device 111 associated with the respective station. However, it should be appreciated that the station may include as many robotic manipulation devices 111 as desired or required for the process or processes performed at the station. Furthermore, one or more stations may not include a robotic manipulation device, e.g., a station associated with process steps that do not require robotic manipulation.

In some embodiments, the barrier 101 between each station and the laboratory environment 102 may define a cavity such that the transportation system 103 may transport the wafer for processing (e.g., a single wafer, a stack of wafers, an associated repository unit, and/or an associated FOUP 109) from the laboratory environment 102, to the respective station for processing, and back to the laboratory environment 102. One or more of the stations, may include a robotic manipulation device 111 operable with the transportation system 103 and/or a robotic transportation device 105 to receive the wafer from the laboratory environment 102, position the wafer for processing within the station, and/or transport the wafer back to the laboratory environment 102. In some embodiments, each station may include a robotic manipulation device 111 suitable to assist in transferring the wafer for processing between the respective station and the laboratory environment 102.

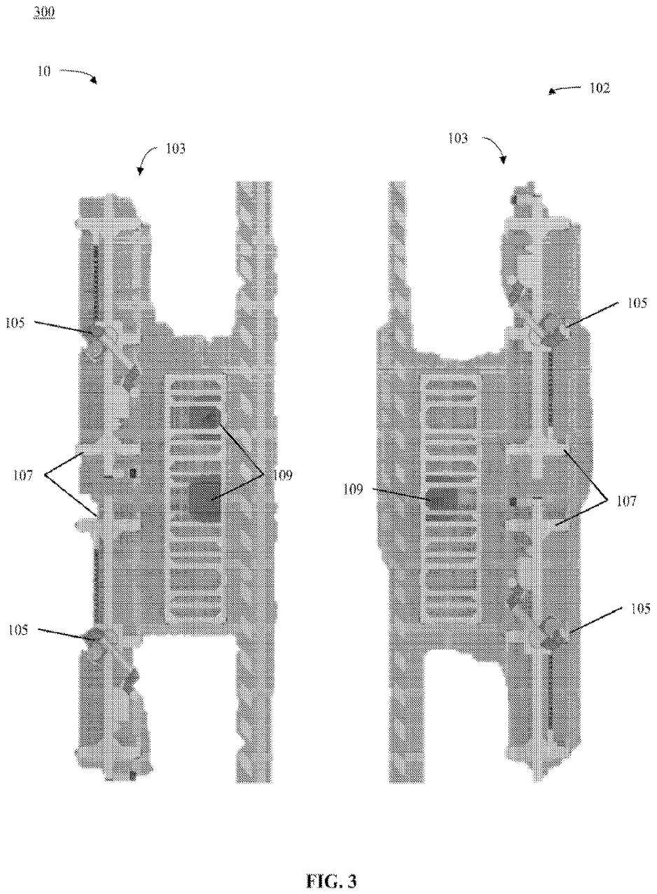

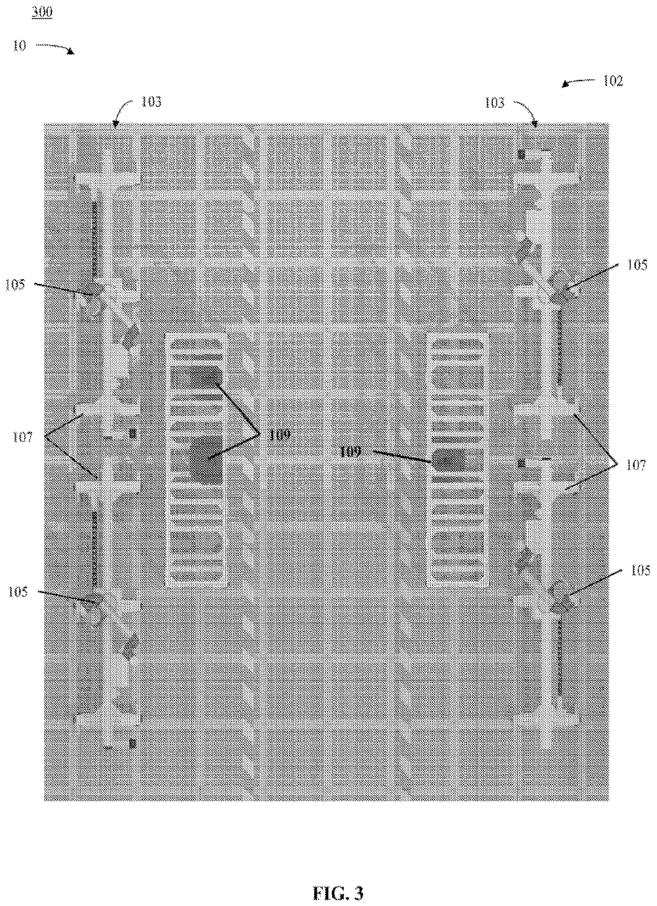

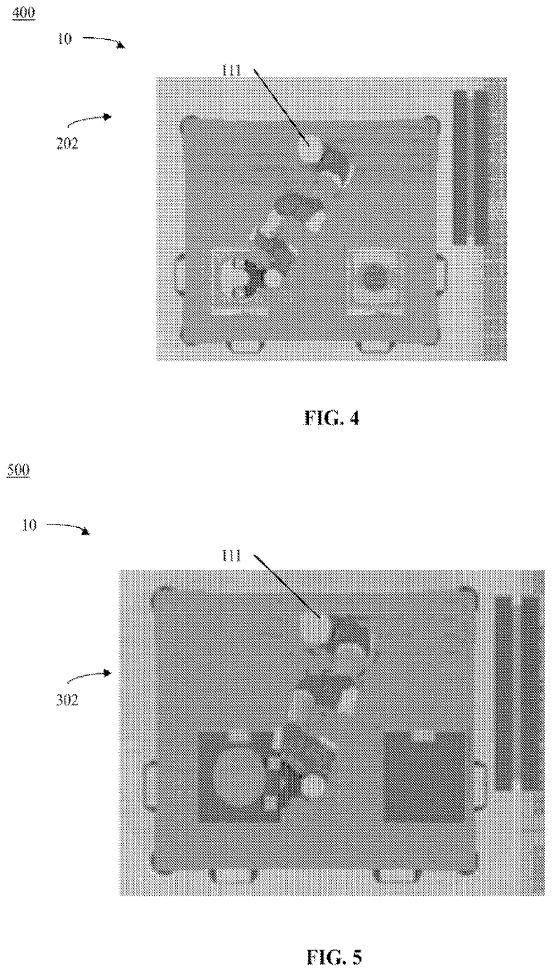

In some embodiments, the system 10 includes a bonding station 202 (see, e.g., FIG. 4) configured to bond the wafer for processing with an additional wafer and/or a carrier. The wafer for processing may be positioned between the laboratory environment 102 and the bonding station 202 utilizing the transportation system 103, an associated transportation device 105, and/or a robotic manipulation device 111. The robotic manipulation device 111 and/or one or more additional or alternative robotic manipulation devices 111 of the bonding station 202 may handle the wafer for processing within bonding station 202 and perform or assist in the performance of processes performed within the bonding station 202. In some embodiments, the wafer for processing is bonded to the additional wafer, e.g., a wafer generally suitable for use in the production of an additional semiconductor from the additional wafer. The wafer for processing may additionally or alternatively be bonded to the carrier. The carrier may be configured to enhance the handling capability of, improve the electrical performance of, and/or reduce the susceptibility of a semiconductor produced from the wafer for processing. The bonding station 202 may include equipment suitable for the bonding of wafers in the production of a semiconductor. Bonding may be performed within the bonding station 202 utilizing thermal means, anodic means, adhesives, and/or the like. For example, the equipment of the bonding station 202 may be configured to adhere two wafers (e.g., mirror-polished wafers) to each other at room temperature, without the application of a macroscopic gluing layer, and/or without the application of external force. In some embodiments, the equipment of the bonding station 202 may be configured for radiation bonding, silicon on insulator bonding, or the like.

In some embodiments, the system 10 includes a deposition station 302 (see, e.g., FIG. 5) configured to deposit one or more layers of material(s) suitable for the production of a semiconductor to the wafer for processing. The wafer for processing may be positioned between the laboratory environment 102 and the deposition station 302 utilizing the transportation system 103, an associated transportation device 105, and/or a robotic manipulation device 111. The robotic manipulation device 111 and/or one or more additional or alternative robotic manipulation devices 111 of the deposition station 302 may handle the wafer for processing within deposition station 302 and perform or assist in the performance of processes performed within the deposition station 302.

The deposition station 302 may include equipment suitable for depositing the layer(s) of material(s) on the wafer for processing and/or depositing material suitable to become circuit materials in a semiconductor. In some embodiments, the layer(s) of material(s) may be applied to the wafer for processing utilizing plasma deposition. The deposition station 302 may include equipment configured to create multiple layers of material(s), one or more UV hardened layers, layers having multiple or different colors, and/or different options for dispensing the layer(s) of material(s). In some embodiments, the deposition station 302 may include a container with pre-deposited wafers, e.g., wafers having deposited the layer(s) of material(s). In such embodiments, the wafer transported from the laboratory environment 102 may be swapped with a wafer having deposited the layer(s) of material(s).

The deposition station 302 may additionally or alternatively include equipment suitable to check, measure, or the like the thickness and statistical uniformity of the wafer for processing. In some embodiments, the deposition station 302 may be configured to allow a user to measure a film thickness of the layer(s) of material(s) deposited within the deposition station 302, such as visually or with the use of one or more instruments. The deposition station 302 may be further configured to allow the user to inspect one or more pieces of associated equipment. For example, prior to the deposition of the wafer for processing, a user may inspect the equipment, instruments, and the like associated with the deposition station 302.

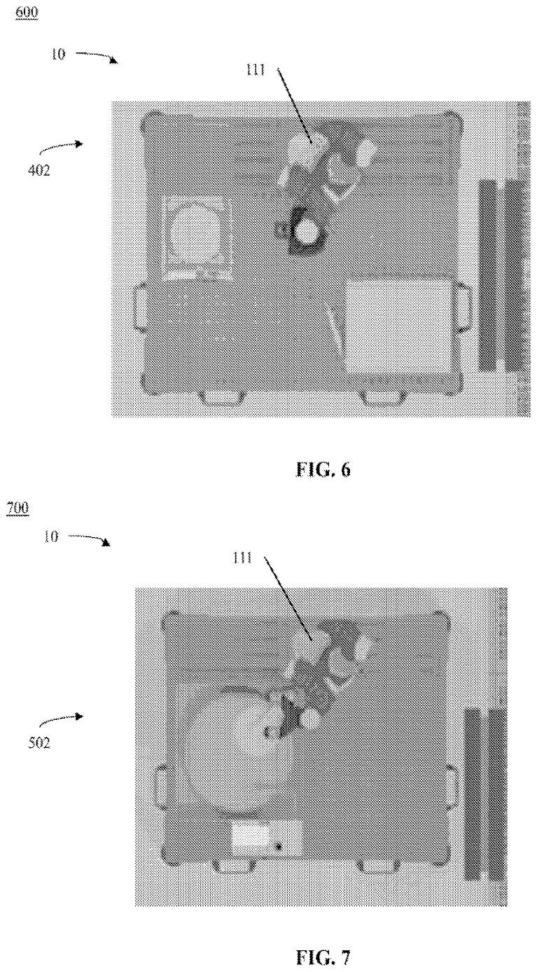

In some embodiments, the system 10 includes a polishing station 402 (see, e.g., FIG. 6) configured to remove subsurface damage associated with the wafer for processing. The wafer for processing may be positioned between the laboratory environment 102 and the polishing station 402 utilizing the transportation system 103, an associated transportation device 105, and/or a robotic manipulation device 111. The robotic manipulation device 111 and/or one or more additional or alternative robotic manipulation devices 111 of the polishing station 402 may handle the wafer for processing within polishing station 402 and perform or assist in the performance of processes performed within the polishing station 402. The polishing station 402 may include equipment suitable for removing subsurface damage associated with the wafer for processing, remove stresses associated with the wafer for processing, and/or prevent warping, which may weaken the wafer for processing.

The polishing station 402 may include equipment configured to for chemical mechanical polishing (CMP), wherein subsurface damage is removed to create thinner and more flexible wafers (e.g., silicon wafers). In some embodiments, the polishing station 402 may include equipment for chemical polishing, mechanical polishing, and/or slurry polishing of the wafer for processing. In some embodiments, the robotic manipulation device(s) 111 associated with the polishing station 402 may maneuver the wafer for polishing to one or more devices for subsequent polishing, such as a rotor machine. During polishing of the wafer for processing, a user may inspect the equipment (e.g. a polishing rotor or the like and the speed or force of the same), instruments, and the like associated with the polishing station 402.

In some embodiments, the system 10 includes a photomask station 502 (see, e.g., FIG. 7) configured to generate a photomask associated with the wafer for processing. The wafer for processing may be positioned between the laboratory environment 102 and the photomask station 502 utilizing the transportation system 103, an associated transportation device 105, and/or a robotic manipulation device 111. The robotic manipulation device 111 and/or one or more additional or alternative robotic manipulation devices 111 of the photomask station 502 may handle the wafer for processing within photomask station 502 and perform or assist in the performance of processes performed within the photomask station 502. The photomask station 502 may include equipment suitable for generating the photomask associated with the wafer for processing. In some embodiments, photolithography may be utilized to generate the photomask associated with the wafer for processing. In some embodiments, the photomask station 502 may include equipment (e.g., a gantry robot or the like) configured to apply a wet coat and/or bake the wet coat. The photomask station 502 may include additional or alternative equipment configured to bake the wafer for processing to produce the photomask. While generating the photomask associated with the wafer for processing, a user may inspect the equipment, instruments, and the like associated with the photomask station 502. For example, the user may inspect the photomask station 502 for resist application, the spin speed of associated equipment, and/or the bake or heating conditions utilized to generate the photomask.

Embodiments of the system 10 may include an etching station 602 (see, e.g., FIG. 7) configured to selectively remove material from wafer for processing and or material from the layer(s) of the same in order to create a chip pattern within the wafer. The wafer for processing may be positioned between the laboratory environment 102 and the etching station 602 utilizing the transportation system 103, an associated transportation device 105, and/or a robotic manipulation device 111. The robotic manipulation device 111 and/or one or more additional or alternative robotic manipulation devices 111 of the etching station 602 may handle the wafer for processing within etching station 602 and perform or assist in the performance of processes performed within the etching station 602. The etching station 602 may include equipment suitable for selectively removing material from the wafer for processing and/or the layers thereof (e.g., one or more materials suitable for producing a semiconductor) in order to create a chip pattern within wafer for processing and/or layer(s) of the same.

Additionally or alternatively, the etching station 602 may be configured to selectively remove material from a thin film on a substrate (with or without prior structures on its surface) and, by this removal, create a pattern of the material on the substrate.

In some embodiments, the etching station 602 may be configured to use plasma etching to generate the chip pattern. The etching station 602 may generally include equipment suitable to utilize lithography to generate the chip pattern within the photomask of the wafer for processing. For example, highly complex circuit patterns may be drawn on the associated photomask and reduced using ultra-high-performance lenses and exposed onto a silicon substrate, e.g., the wafer for processing. In some embodiments, the robotic manipulation device(s) 111 and/or the transportation device(s) 105 associated with the etching station 602 may maneuver the wafer for processing to a tank, vat, or the like and dip the wafer into a hot liquid bath (e.g., hot water bath) in order to generate the chip pattern within the layer(s) of material under the photomask.

Within the etching station 602, a user may check the conditions affecting optical pattern generation (e.g., light output, wafer vacuum and compressed air, and/or the reticle or photomask installation). Additionally or alternatively, the user may inspect the equipment, instruments, and the like associated with the etching station 602. For example, the user may inspect the plasma process equipment and/or the components thereof. The user may visually inspect the plasma process conditions. The user may further or alternatively inspect the wafer for processing after the chip pattern has been generated, e.g., a visual inspection or a microscopic inspection of the wafer for processing after etching performed within the etching station 602.

Embodiments of the system 10 may include a stripping station 702 (see, e.g., FIG. 9) configured to remove residual photoresist material. The wafer for processing may be positioned between the laboratory environment 102 and the stripping station 702 utilizing the transportation system 103, an associated transportation device 105, and/or a robotic manipulation device 111. The robotic manipulation device 111 and/or one or more additional or alternative robotic manipulation devices 111 of the stripping station 702 may handle the wafer for processing within stripping station 702 and perform or assist in the performance of processes performed within the stripping station 702.

The stripping station 702 may include equipment suitable to remove the residuals of photoresist material from the wafer for processing (e.g., subsequent to etching and/or processing in the etching station 602). For example and in some embodiments, plasma and/or a laser may be configured to remove residual photoresist material, inspect the wafer for processing, or both. In some embodiments, the transportation device(s) 105 associated with the stripping station 702 may maneuver the wafer for processing to a strip bath. Additionally or alternatively, the transportation device(s) 105 associated with the stripping station 702 may maneuver the wafer for processing to a rinse bath.

In some embodiments, a user may perform an initial check of the wafer for processing within the stripping station 702, such as a visual inspection, such as a microscopic inspection. The stripping station 702 may be configured such that the user may inspect the equipment (e.g., the strip bath temperature, the number of stripping processes performed subsequently utilizing the current strip bath, determine the remaining life cycles of the strip bath, prepare a new strip bath, the temperature of the rinse bath, the resistivity of the rinse bath, and/or prepare a new rinse bath), instruments, and the like associated with the stripping station 702. While stripping the wafer for processing, the user may monitor the time the wafer is in the strip bath and/or the rinse bath. In some embodiments, the user may perform one or more post stripping checks (e.g., subsequent to use of the strip bath and/or the rinse bath) of the wafer for processing within the stripping station 702, such as a visual inspection, such as a microscopic inspection.

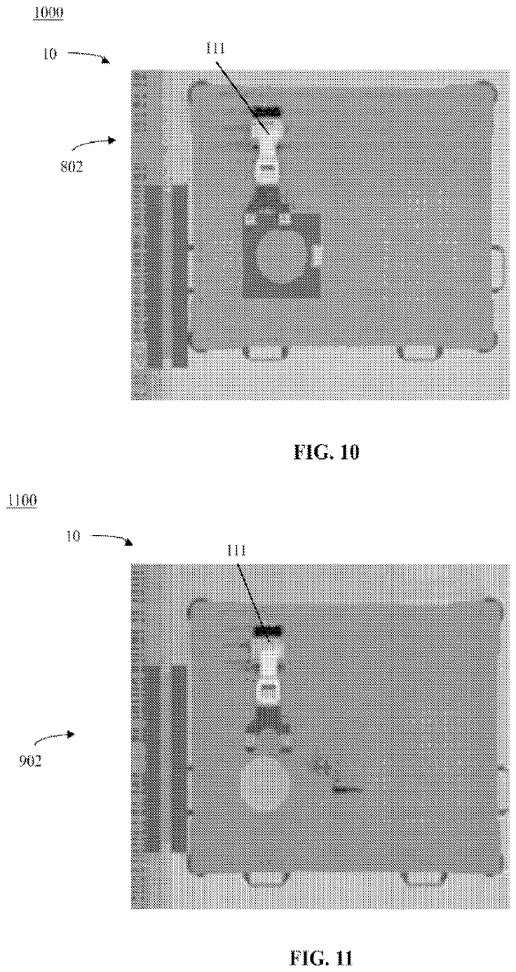

Embodiments of the system 10 may include a cleaning and inspection station 802 (see, e.g., FIG. 10) configured to perform a post stripping clean and inspection. The wafer for processing may be positioned between the laboratory environment 102 and the cleaning and inspection station 802 utilizing the transportation system 103, an associated transportation device 105, and/or a robotic manipulation device 111. The robotic manipulation device 111 and/or one or more additional or alternative robotic manipulation devices 111 of the cleaning and inspection station 802 may handle the wafer for processing within cleaning and inspection station 802 and perform or assist in the performance of processes performed within the cleaning and inspection station 802.

The cleaning and inspection station 802 may include equipment suitable to perform a final clean and inspection prior to the use of metrology. For example and in some embodiments, the transportation device(s) 105 associated with the cleaning and inspection station 802 may maneuver the wafer for processing to a water bath for cleaning and/or dip the wafer into the water bath. In some embodiments of the cleaning and inspection station 802, the transportation device(s) 105 may maneuver the wafer for processing to inspection equipment configured to assess the alignment of the wafer. Additionally or alternatively, robotic probing may be utilized to provide advanced alignment evaluation. The cleaning and inspection station 802 may generally include equipment suitable to utilize mecademic robot systems for probing and assessing the wafer for processing. In some embodiments, the cleaning and inspection station 802 may include equipment configured to package silicon photonic devices.

In some embodiments, the station 802 may be configured such that a user may visually inspect the wafer for processing for residue(s), line roughness, or both. The cleaning and inspection station 802 may additionally or alternatively be configured such that the user may microscopically inspect (e.g., utilizing a microscope with a reticle) the wafer for processing for residue(s), line roughness, or both. In some embodiments, the user may inspect the equipment (e.g., inspection of the surface of the water bath), instruments, and the like associated with the cleaning and inspection station 802.

Embodiments of the system 10 may include a surface preparation station 902 (see, e.g., FIG. 11) configured to resize or reshape the wafer for processing. The wafer for processing may be positioned between the laboratory environment 102 and the surface preparation station 902 utilizing the transportation system 103, an associated transportation device 105, and/or a robotic manipulation device 111. The robotic manipulation device 111 and/or one or more additional or alternative robotic manipulation devices 111 of the surface preparation station 902 may handle the wafer for processing within surface preparation station 902 and perform or assist in the performance of processes performed within the surface preparation station 902. The surface preparation station 902 may include equipment suitable to grind the wafer for processing to the correct size, to shape one or more edges of the wafer, or both. For example and in some embodiments, the periphery of the wafer for processing may be ground to attain the required product diameter. Various types of grinding stones or the like may be utilized to shape the wafer edge to meet unique edge shape.

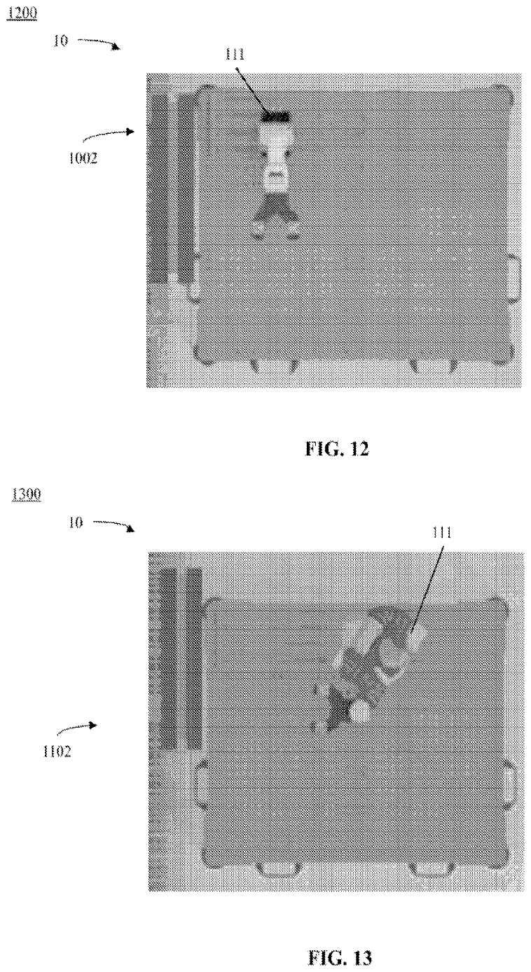

Embodiments of the system 10 may include a metrology station 1002 (see, e.g., FIG. 12) configured for inspection of the wafer for processing and/or thin film in-line section after semiconductor processing. The wafer for processing may be positioned between the laboratory environment 102 and the metrology station 1002 utilizing the transportation system 103, an associated transportation device 105, and/or a robotic manipulation device 111. The robotic manipulation device 111 and/or one or more additional or alternative robotic manipulation devices 111 of the metrology station 1002 may handle the wafer for processing within metrology station 1002 and perform or assist in the performance of processes performed within the metrology station 1002.

The metrology station 1002 may include equipment suitable to inspect the wafer, perform thin film in-line inspection and various optical, mechanical, and electrical measurements as required to assess semi-device performance and wafer integrity. In some embodiments, the transportation device(s) 105 and/or the robotic manipulation device(s) 111 associated with the metrology station 1002 may maneuver the wafer for processing to optical metrology equipment, such as semi-automated optical metrology equipment. Additionally or alternatively, the transportation device(s) 105 and/or the robotic manipulation device(s) 111 associated with the metrology station 1002 may maneuver the wafer for processing to surface probe metrology equipment, such as semi-automated surface probe metrology equipment.

Embodiments of the metrology station 1002 may be configured such that the user may inspect the equipment, instruments, and the like associated with the metrology station 1002. Additionally or alternatively, the metrology station 1002 may be configured such that the user may remove the wafer for processing from an associated cassette, place the wafer for processing within the optical metrology equipment, operate the optical metrology equipment, place the wafer for processing within the surface probe metrology equipment, operate the surface probe metrology equipment, verify that the wafer for processing meets SPC control requirements, and/or visually inspect the wafer for processing for post processing quality assurance.

Embodiments of the system 10 may include a debonding station 1102 (see e.g., FIG. 13) configured to separate the wafer and the additional wafer and/or the carrier after bonding. The wafer for processing may be positioned between the laboratory environment 102 and the debonding station 1102 utilizing the transportation system 103, an associated transportation device 105, and/or a robotic manipulation device 111. The robotic manipulation device 111 and/or one or more additional or alternative robotic manipulation devices 111 of the debonding station 1102 may handle the wafer for processing within debonding station 1102 and perform or assist in the performance of processes performed within the debonding station 1102.

The debonding station 1102 may include equipment suitable to soften the bonded structure and/or cause the bonded structure to slowly slide past one another until the components thereof are separated. For example and in some embodiments, the bonded structure may be heated above the softening temperature of the bonding material and an opposing shear force is applied to the wafer for processing, the additional wafer(s), and/or the carrier, causing them to slowly slide past one another until the bonded structure is separated. Additionally or alternatively, the debonding station 1102 may include equipment suitable to electronically test the wafer for processing. For example and in some embodiments, a manual probe and/or a “GO/ NO GO” evaluation equipment, and/or the like may be utilized to assess the electrical performance of the wafer for processing. Embodiments of the debonding station 1102 may be configured such that the user may inspect the equipment, instruments, and the like associated with the debonding station 1102.

Particular embodiments and features have been described with reference to the drawings. It is to be understood that these descriptions are not limited to any single embodiment or any particular set of features. Similar embodiments and features may arise or modifications and additions may be made without departing from the scope of these descriptions and the spirit of the appended claims. The foregoing description provides embodiments of the invention by way of example only. It is envisioned that other embodiments may perform similar functions and/or achieve similar results. Any and all such equivalent embodiments and examples are within the scope of the present invention and are intended to be covered by the appended claims.

What is claimed is:

1. A system for simulating the production of a semiconductor from a wafer suitable for use in the production of a semiconductor from the wafer, the system comprising:
a central laboratory hub including at least one barrier defining a laboratory environment such that the at least one barrier substantially encloses the laboratory environment;
a plurality of stations, each station of the plurality of stations operatively coupled to the central laboratory hub such that the wafer may be selectively positioned between the respective station and the laboratory environment, the plurality of stations comprising:
a deposition station configured to deposit at least one layer of material suitable for the production of a semiconductor to the wafer;
a photomask station configured to generate a photomask associated with the wafer; and
an etching station configured to generate a circuit pattern within the photomask associated with the wafer; and
a transportation system configured to operate within the laboratory environment and to transport the wafer from the central laboratory hub to at least one station of the plurality of stations.

2. The system of claim 1, wherein the etching station is configured to selectively remove material from the at least one layer of material in order to create a chip pattern within the at least one layer of material.

3. A method of simulating the production of a semiconductor from a wafer, the method comprising:
positioning, utilizing a transportation system configured to operate within a laboratory environment defined by at least one barrier of a central laboratory hub that substantially enclose the laboratory environment, a wafer from the laboratory environment to a deposition station;
depositing at least one layer of material suitable for the production of a semiconductor to the wafer;
positioning, utilizing the transportation system, the wafer from the laboratory environment to a photomask station;
generating a photomask associated with the wafer;
positioning, utilizing the transportation system, the wafer from the laboratory environment to the etching station; and
generating a circuit pattern within the photomask associated with the wafer.

4. The method of claim 3, further comprising:
positioning, utilizing the transportation system, the wafer from the laboratory environment to an etching station.

5. The method of claim 4, further comprising:
selectively removing material from the at least one layer of material in order to create a chip pattern within the at least one layer of material.

6. The method of claim 5, further comprising:
positioning, utilizing the transportation system, the wafer from the etching station to the laboratory environment.

7. The method of claim 3, further comprising:
positioning, utilizing the deposition station, the wafer from the deposition station to the laboratory environment.

8. The method of claim 3, further comprising:
positioning, utilizing the transportation system, the wafer from the etching station to the laboratory environment.

9. The method of claim 3, further comprising:
positioning a plurality of wafers in the laboratory environment, each wafer of the plurality of wafers suitable for use in the production of a semiconductor from the wafer.

10. The method of claim 9, wherein the plurality of wafers are loaded into at least one repository unit positioned within the laboratory environment.

11. The method of claim 3, further comprising:
loading a plurality of wafers into at least one repository unit associated with the transportation system, each wafer of the plurality of wafers suitable for use in the production of a semiconductor from the wafer.
